(19) United States
(12) Patent Application Publication
(10) Pub. No.: US 2006/0060301 A1
(43) Pub. Date: Mar. 23, 2006

(54) Substrate processing using molecular self-assembly

(76) Inventors: David E. Lazovsky, San Jose, CA (US); Tony P. Chiang, San Jose, CA (US); Sandra G. Malhotra, San Jose, CA (US)

Correspondence Address: COURTNEY STANIFORD & GREGORY LLP, P.O. BOX 9686, SAN JOSE, CA, 95157, US

(21) Appl. No.: 11/231,047

(22) Filed: Sep. 19, 2005

Related U.S. Application Data
(63) Continuation-in-part of application No. 11/132,817, filed on May 18, 2005.
(63) Continuation-in-part of application No. 11/132,841, filed on May 18, 2005.
(60) Provisional application No. 60/610,937, filed on Sep. 17, 2004.

(51) Int. Cl. H01L 21/306; C23F 1/00

(52) U.S. Cl. 156/345.26; 156/345.27; 156/345.1; 156/345.24

(57) ABSTRACT

A system for molecular self-assembly referred to herein as a “molecular self-assembly system (MSAS)” includes at least one interface configured to receive at least one substrate. The MSAS also includes at least one molecular self-assembly module coupled to the interface. The MSAS can also include one or more of pre-processing modules, other molecular self-assembly processing modules, and post-processing modules, and may include any number, combination, and/or type of other modules. Each module of the MSAS can contain at least one of a number of different processes as appropriate to a processing configuration of the MSAS. The MSAS also includes at least one handler coupled to the interface and configured to move the substrate between the interface and one or more of the modules.

### RELATED APPLICATIONS

This application claims the benefit of U.S. Patent Application 60/610,937, filed Sep. 17, 2004. This application is also a continuation-in-part application of U.S. patent application Ser. Nos. 11/132,817 and 11/132,841, both filed May 18, 2005.

### TECHNICAL FIELD

The disclosure herein relates generally to processing a substrate to form material on the substrate and, more particularly, to using molecular self-assembly in substrate processing to form material on a substrate.

### BACKGROUND

The manufacture of a variety of products now requires the cost-effective production of very small structures and features, e.g., structures and features having a characteristic dimension at the micrometer or nanometer size scale. Electronic components (microprocessors, memory chips, etc.) for computers and other devices are well-known examples of such products. The never-ending pursuit of electronic components including smaller structures and features is leading increasingly to a need to be able to cost-effectively process the semiconductor substrates with which such components are made to produce structures and features at the nanometer size scale. Other products too, such as flat panel displays, can benefit from substrate processing capability that enables cost-effective production of such small structures and features.

Molecular self-assembly is a technique that can be used to produce very small structures and features, e.g., structures and features having a characteristic dimension at the nanometer size scale. Molecular self-assembly can be used to produce a variety of material formations, such as molecular monolayers (often referred to as self-assembled monolayers, or SAMs), molecular multilayers and nanostructures (e.g., nanotubes, Buckey balls, nanowires). However, to date, molecular self-assembly has not been introduced into commercial production processes used to create products as described above which require production of very small structures and features. Consequently there is a need to use molecular self-assembly in substrate processing to form material on a substrate.

Incorporation by Reference

Each publication, patent, and/or patent application mentioned in this specification is herein incorporated by reference in its entirety to the same extent as if each individual publication and/or patent application was specifically and individually indicated to be incorporated by reference.

### BRIEF DESCRIPTION OF THE DRAWINGS

FIG. 1 is a flow diagram for processing a substrate using molecular self-assembly, under an embodiment.

FIG. 2 is a substrate. processing system using molecular self-assembly, under an embodiment.

FIG. 3 is a substrate processing system using molecular self-assembly, under an alternative embodiment.

FIG. 4 is a substrate processing system using molecular self-assembly, under another alternative embodiment.

FIG. 5 is a flow diagram for forming a capping layer on electrically conductive regions separated by a dielectric region, under the molecular self-assembly of an embodiment.

FIGS. 6A through 6E show cross-sectional views of an electronic device undergoing formation of a capping layer on electrically conductive regions separated by a dielectric region, under the molecular self-assembly of an embodiment.

FIGS. 7A through 7E show a cross-section of a structure including a dielectric region on which a masking layer and a capping layer are formed, and the capping layer is subsequently removed, using the molecular self-assembly of an embodiment.

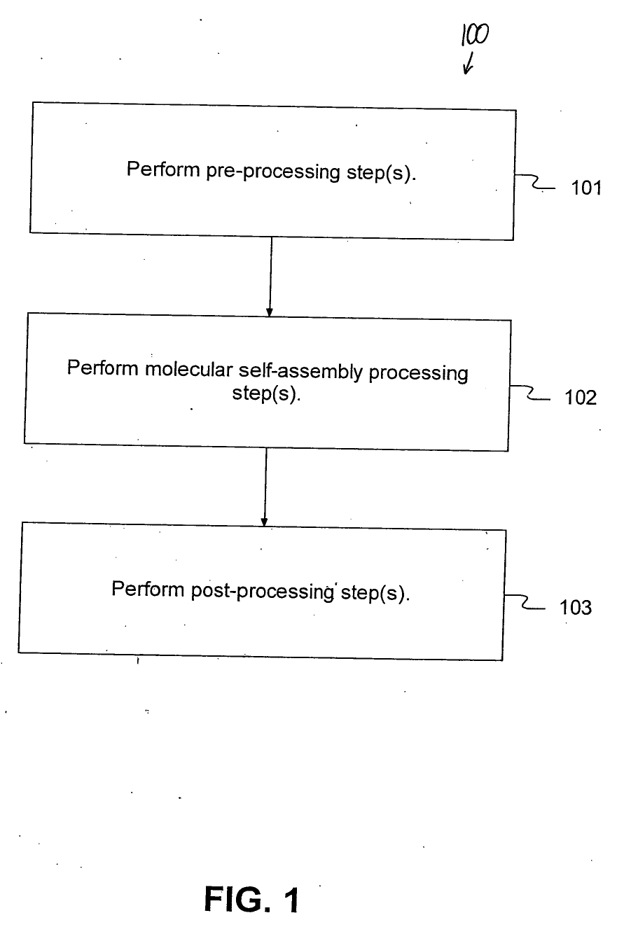

In the drawings, the same reference numbers identify identical or substantially similar elements or acts. To easily identify the discussion of any particular element or act, the most significant digit or digits in a reference number refer to the Figure number in which that element is first introduced (e.g., element 100 is first introduced and discussed with respect to FIG. 1).

### DETAILED DESCRIPTION

Systems and methods for molecular self-assembly are described below for use in forming material(s) on a substrate. The use of the systems and methods for molecular self-assembly, collectively referred to herein as “molecular self-assembly,” enables production of very small structures and features on substrates (e.g., at the nanometer size scale) at very low cost, which can be useful in the commercial manufacturing of a variety of products, such as electronic components and flat panel displays to name a few.

A system for molecular self-assembly is referred to herein as a “molecular self-assembly system” or “MSAS” and includes at least one interface configured to receive at least one substrate. The MSAS also includes a number of modules coupled to the interface. The modules include a pre-processing module, a molecular self-assembly processing module, and a post-processing module, but may include any number and/or type of other modules where any of the modules may include functions of the pre-processing, molecular self-assembly, and/or post-processing modules. The MSAS is not required to include at least one of each of the preceding module types; for example, a particular process flow may include only the molecular self-assembly processing module and means for moving a substrate into and out of the MSAS. Also, functions of all of the pre-processing, molecular self-assembly, and post-processing modules may be embedded within a single module. Each module of the multiple modules can contain at least one of a number of different processes as appropriate to processes contained in at least one other of the modules. The MSAS also includes at least one handler coupled to the interface and configured to move the substrate between the interface and one or more of the modules.

The molecular self-assembly of an embodiment is used in one or more substrate processing systems and processes to form material (e.g., produces a layer or structure) on a substrate. The forming of material on a substrate as used herein encompasses both forming the material directly on the substrate material as well as forming the material on another material previously formed on the substrate, but may not be so limited. The molecular self-assembly enables production of very small structures and features on substrates (e.g., at the nanometer size scale) at very low cost, which can be useful in the manufacture of a variety of products. Molecular self-assembly is also particularly suitable for forming material with good selectivity, a very useful characteristic in substrate processing that has previously been difficult to achieve. Additionally, the molecular self-assembly can take advantage of one or more capabilities enabled by commercial substrate processing apparatus and methods (e.g., commercial semiconductor processing equipment and methods) to facilitate and/or enhance the performance of molecular self-assembly to form material on a substrate.

The molecular self-assembly can be used for a wide variety of applications and in the cost-effective production of products (e.g., electronic components, such as processors and memories, among others) including the increasingly small structures and features demanded by developing and future generations of technology. For example, the applications and/or products include but are not limited to the processing of a semiconductor substrate, processing one or more semiconductor wafers for use in production of electronic components, processing of a substrate for use in production of a flat panel display, producing anti-stiction layers for micro-electromechanical machines (MEMs), producing active molecular electronic components (such as capacitors and transistors) for bottom-up manufacturing of logic and memory integrated circuits, producing release layers for micro-contact printing or step-and-flash lithographic applications. As can be appreciated, there are many other applications of the molecular self-assembly.

The molecular self-assembly of an embodiment can form a variety of materials in a variety of types of layers or structures. In general, the molecularly self-assembled material can be organic or inorganic. The molecular self-assembly can be used to produce one or more of a molecular monolayer and a molecular multilayer. The molecular self-assembly also produces a nanostructure (e.g., nanotube, Buckey ball, nanowire). The molecular self-assembly can make use of chemical self-assembly or directed self-assembly.

The molecular self-assembly can be used in the processing of a substrate comprising any type of material. For example, the molecularly self-assembled material can be formed on material previously formed on a substrate and can be formed on material (substrate or other material) that has been functionalized to have desired properties, such as desired adhesion characteristics. In particular, the molecular self-assembly can be used in processing semiconductor substrates as in the manufacture of components for use in the electronics industry. The molecular self-assembly can also be used in processing substrates like glass, silicon, and/or plastic for use in the production of flat panel displays, for example. The molecular self-assembly can be used in the processing of any type of semiconductor substrate, including but not limited to silicon substrates, silicon-on-insulator substrates, silicon carbide substrates, strained silicon substrates, silicon germanium substrates, and gallium arsenide substrates.

The molecular self-assembly can include a substrate of any size. For example, the molecular self-assembly can be used in the processing of small semiconductor substrates having areas of less than one square inch up to twelve (12) inch (300 millimeter (mm)) or larger semiconductor substrates used in the production of many electronic components. In general, there is no limit to the size of substrates that can be processed. For example, the molecular self-assembly can be used to process each succeeding larger generation of semiconductor substrates used to produce electronic components. The molecular self-assembly can also be used to process the relatively large substrates that are used in the production of flat panel displays. Such substrates include rectangular substrates on the order of approximately one square meter, but larger substrates can be used. The molecular self-assembly can also be scaled for use in roll-to-roll processing applications for flexible substrates having a fixed width, but (theoretically) unlimited length (a manner of substrate processing that can be particularly useful in the production of flat panel displays); for example, such substrate rolls can be hundreds of feet long.

The molecular self-assembly can be used in processing substrates of any shape, e.g., circular, rectangular (including square), etc. For example, and as described above, the molecular self-assembly can be used in the processing of semiconductor substrates used in the production of electronic components (e.g., circular substrates), as well as in the processing of substrates used in the production of flat panel displays (e.g., rectangular substrates).

The molecular self-assembly can be used in the processing of a single substrate or multiple substrates (e.g., batch processing). For example, in wet semiconductor processing, a single substrate can be processed or a batch of, for example, 13, 25 or 50 substrates can be processed at a single time. In dry semiconductor processing and flat panel display production, typically, a single substrate is processed at one time.

The molecular self-assembly described herein can include wet processing and/or dry processing. In wet processing, a substrate is processed using a fluid. For example, the substrate can be immersed, in whole or in part, in a fluid having specified characteristics (e.g., a specified chemical composition). Also, for example, a fluid can be sprayed on to the substrate in a specified manner. Wet processing for use with the molecular self-assembly of an embodiment can make use of any of a variety of chemical constituents, as appropriate for the desired processing.

In dry processing (e.g., physical vapor deposition, chemical vapor deposition, plasma-enhanced chemical vapor deposition, and atomic layer deposition), a plasma or gas is used to produce a desired interaction with a substrate that processes a substrate surface in a specified way. Dry processing for use with the molecular self-assembly can make use of inert or reactive gases, as appropriate for the desired processing.

Any of a variety of chemical constituents or other reactants (collectively referred to herein as constituents or chemical constituents) can be used by a molecular self-assembly system of an embodiment to effect molecular self-assembly and related processes. The constituents can be in the liquid phase, gaseous phase, and/or some combination of the liquid and gaseous phases (including, for example, the super-critical fluid phase). The constituents used and their concentrations, as well as the mixture of constituents, will depend on the particular process step(s) to be performed. The chemical delivery system can enable precise control of the molar concentrations, temperature, flow rate and pressure of chemical constituents as appropriate to the process. The chemical delivery system can also provide appropriate filtration and control of contamination.

In the following description, numerous specific details are introduced to provide a thorough understanding of, and enabling description for, embodiments of the molecular self-assembly. One skilled in the relevant art, however, will recognize that these embodiments can be practiced without one or more of the specific details, or with other components, systems, etc. In other instances, well-known structures or operations are not shown, or are not described in detail, to avoid obscuring aspects of the disclosed embodiments.

FIG. 1 is a flow diagram for processing 100 a substrate using molecular self-assembly, under an embodiment. The processing 100 includes pre-processing 101, molecular self-assembly processing 102, and post-processing 103. Each of the pre-processing 101, molecular self-assembly processing 102, and post-processing 103 may include one or multiple processes or processing steps but is not so limited. Various implementations of each of the pre-processing 101, molecular self-assembly processing 102 and post-processing 103 are described below. Aspects of the molecular self-assembly of an embodiment relate to implementation of part or all of the pre-processing 101, molecular self-assembly processing 102 and/or post-processing 103 in a particular manner and/or using particular apparatus.

The pre-processing 101 prepares the substrate for formation of a desired material in the molecular self-assembly processing 102. The particular pre-processing 101 may depend on processes of the molecular self-assembly 102, i.e., the characteristics of the processes and material(s) formed. The pre-processing 101 can include one or more wet pre-processing processes, one or more dry pre-processing processes, and/or a combination of wet pre-processing and dry pre-processing.

Generally, in an embodiment, any pre-processing 101 can be used that is necessary or desirable to prepare the substrate for material formation in the molecular self-assembly processing 102. For example, the substrate can be cleaned to remove contaminants and/or the substrate can be functionalized in a manner that facilitates formation of the material in the molecular self-assembly processing 102. As used herein, functionalization of a material refers to modifying the characteristics of an exposed part of the material to achieve a desired interaction with another material subsequently formed on the exposed part of the material. For instance, the pre-processing 101 of an embodiment establishes the adhesion properties of a surface on which material is to be formed in the molecular self-assembly processing 102 to improve adhesion of the formed material on that surface. If, for instance, a molecule to be formed on a surface adheres only to a hydroxyl (OH) group, then the surface can be functionalized to expose hydroxyl groups on that surface. There are many other ways contemplated under the molecular self-assembly described herein in which surface(s) on which material(s) are to be formed in subsequent processes can be functionalized; functionalizing surface(s) to facilitate adhesion of subsequently formed material(s) is only one example of functionalization.

In one aspect of the molecular self-assembly, one or more parameters of wet pre-processing can be controlled to facilitate or enhance performance of that processing. For instance, parameter(s) of wet pre-processing can be controlled to reduce the time required for the desired processing, to enable better control over physical characteristics (such as temperature) of the processing, and/or to enable defect-free processing. In particular, one or more parameters of wet pre-processing can be controlled to facilitate or enhance performance of that processing to effect desired processing of a substrate material (e.g., functionalization of a substrate material) on which material will subsequently be formed using molecular self-assembly. The molecular self-assembly can make use of capabilities that are provided by existing commercial substrate processing apparatus (e.g., conventional semiconductor processing apparatus), or that can be provided with some modification of such apparatus, to effect control of one or more parameters associated with wet pre-processing to enhance performance of that processing.

For example, vibration can be imparted to a substrate during wet pre-processing (e.g., being immersed in a fluid bath or sprayed with a fluid). More generally, vibration can be imparted to a substrate during any wet processing processes. For example, vibration can be imparted to a substrate to facilitate a cleaning process. The frequency and/or amplitude of vibration imparted to a substrate while undergoing wet processing is chosen so as to be appropriate for the process. For example, the molecular self-assembly can include application of high frequency vibration, such as ultrasonic or megasonic vibration, to a substrate during wet processing to facilitate a desired functionalization and/or cleaning of a substrate material on which material will subsequently be formed using molecular self-assembly. The use of vibration of a substrate during wet pre-processing can enhance reaction kinetics and/or reaction efficiency so as to reduce the time required for the processing. The substrate can also be rotated to improve kinetics, reaction efficiency and/or uniformity of processing across the substrate.

The molecular self-assembly of an embodiment can also be implemented to control the fluid dynamics of wet pre-processing. Appropriate control of the fluid dynamics of wet pre-processing, in accordance with the molecular self-assembly, can advantageously promote a desired functionalization of a surface or surfaces. The fluid dynamics can be controlled in a manner that is the same as, or similar to, that described below with respect to the control of the fluid dynamics during the molecular self-assembly processing 102.

The molecular self-assembly can also be implemented to control temperature during wet pre-processing. The temperature control includes control of the temperature of the fluid used during wet pre-processing (e.g., by controlling the temperature of one or more chemicals used) and/or the temperature of the substrate. In either case, the temperature can be controlled using closed or open loop control. Appropriate control of the fluid or substrate temperature during wet pre-processing can enable control over the temperature at which the processing occurs. For instance, some wet pre-processing produces an exothermic reaction that may cause the temperature of the process to elevate out of control. The molecular self-assembly can be used to monitor the process temperature and compensate accordingly (e.g., adjust temperature(s) used in the delivery of chemical(s) for use in the wet processing). Processes that produce an endothermic reaction can be similarly controlled.

In another aspect of the molecular self-assembly, dry pre-processing is used to effect desired processing of a substrate material (e.g., functionalization of a substrate material) on which material will subsequently be formed using molecular self-assembly. In particular, a plasma process can be used. The plasma pre-processing can be implemented so that the substrate is exposed to the plasma or so that the substrate is not exposed to the plasma (i.e., so that the plasma is remote). The latter can be desirable because such processing may be less damaging to the substrate. The plasma pressure and bias power can be controlled to produce desired processing. Plasma pre-processing in an embodiment can be performed using one or more of a variety of chemical constituents, such as, for example, oxygen, hydrogen, nitrogen and ammonia. For example, plasma pre-processing can be used to oxidize a substrate surface by exposing the surface to oxygen plasma. Alternatively, for example, plasma pre-processing can be used to reduce or eliminate oxidation of a substrate surface by exposing the surface to hydrogen plasma. The latter can be useful, for example, to reduce or eliminate surface oxidation that may occur as a substrate is moved around a production facility during processing (e.g., as a semiconductor wafer is moved around a semiconductor fabrication facility). The molecular self-assembly can make use of existing commercial substrate processing apparatus (e.g., conventional semiconductor processing apparatus) to effect dry pre-processing.

In another aspect of the molecular self-assembly, both wet pre-processing and dry pre-processing are used to effect desired processing of a substrate material on which material will subsequently be formed using molecular self-assembly. In general, any number and combination of any types of wet pre-processing and dry pre-processing can be used. For example, any combination of the examples of wet pre-processing and dry pre-processing described above can be used to effect desired processing of a substrate material on which material will subsequently be formed using molecular self-assembly.

The molecular self-assembly processing 102 is used to form a material on a substrate. The molecular self-assembly processing 102 can include one or more of wet post-processing processes, one or more dry post-processing processes, and/or a combination of wet post-processing and dry post-processing processes. In general, the molecular self-assembly processing 102 can be performed using existing commercial substrate processing apparatus (e.g., conventional semiconductor processing apparatus), with modification or addition as necessary for the particular processing to be performed. The molecular self-assembly processing 102 includes formation of a material on a substrate using molecular self-assembly.

Molecular self-assembly can be used to form any of a variety of materials in any of a variety of structures (e.g., monolayer, multilayer, nanostructure). For example, the system of an embodiment can use molecular self-assembly to produce a self-assembled monolayer for a CMOS interconnect application, such as a self-assembled monolayer to act as an interface of adhesion between materials (e.g., between a low-k dielectric and a copper barrier such as tantalum nitride).

The system of an embodiment can also use molecular self-assembly to produce a self-assembled monolayer to act as an adhesion layer between a copper barrier and a copper seed layer. The molecular self-assembly processing 102 can also include one or more additional processes in addition to processes for performing molecular self-assembly. For example, after formation of a material on a substrate using molecular self-assembly, one or more processes can be performed to functionalize the material. Any functionalization process can be used in concert with the molecular self-assembly of an embodiment.

For example, a material formed using molecular self-assembly can be functionalized to improve the adhesion properties of that material with respect to a material subsequently to be formed on the molecularly self-assembled material. Alternatively, for example, a material formed using molecular self-assembly can be functionalized to promote subsequent growth of a material. As an example, an organo-metallic terminal group can be used as a seed layer to promote subsequent deposition via chemical vapor deposition, atomic layer deposition, electroless deposition, and electrochemical deposition. Numerous other methods for functionalizing a molecularly self-assembled material are contemplated under the embodiments described herein.

The molecular self-assembly systems and methods described herein include any molecular self-assembly process. Molecular self-assembly can be used to form material directly on surface(s) of a substrate being processed. Alternatively, molecular self-assembly can be used to indirectly form material on surfaces(s) of a substrate (referred to herein as the primary substrate) being processed by forming molecularly self-assembled material (e.g., a self-assembled monolayer) on a blank (i.e., a substrate that is used just for forming the molecularly self-assembled material, referred to herein as the secondary substrate), functionalizing the molecularly self-assembled material, then stamping the molecularly self-assembled material onto specified surface(s) of the primary substrate. The stamping can be done using equipment particularly tailored for that purpose.

The stamping may accelerate substrate processing since the molecularly self-assembled material can have previously been formed on the blank. The stamping can also help ensure that the molecularly self-assembled material is as defect-free as possible, since the molecularly self-assembled material can be formed on the secondary substrate using processes and equipment particularly tailored for that purpose. The molecularly self-assembled material can be functionalized (as appropriate) and the substrate subjected to post-processing 103, whether the molecularly self-assembled material is formed directly or indirectly on the primary substrate.

As described above, molecular self-assembly is particularly suitable for forming material with good selectivity, a very useful characteristic in substrate processing that can be difficult to achieve. For example, the molecular self-assembly can form material so that the molecularly self-assembled material adheres to a particular type of material (which may be without regard to structure or geometry) and/or to a material having a particular structure or geometry. This can be accomplished, for example, by appropriately forming and/or functionalizing the material on which the molecularly self-assembled material is to be formed and performing the molecular self-assembly in a manner tailored to such formation and/or functionalization. For instance, molecular self-assembly can be performed to form material that adheres to a metallic material (or, in other implementations, to a non-metallic material), the underlying material on which the molecularly self-assembled material is to be formed having been previously formed and/or functionalized to present a metallic surface (or, in other implementations, a non-metallic surface) for adhesion of the molecularly self-assembled material.

As with the pre-processing 101, one or more parameters of one or more of the molecular self-assembly processing 102 can be controlled to facilitate or enhance performance of that processing, e.g., reduce the time required for the desired processing, enable better control over physical characteristics (such as temperature) of the processing, and/or enable defect-free processing. Also as with the pre-processing 101, the molecular self-assembly can make use of capabilities that are provided by existing commercial substrate processing apparatus (e.g., conventional semiconductor processing apparatus), or that can be provided with some modification of such apparatus, to effect control of one or more parameters associated with one or more of the molecular self-assembly processing 102 to enhance performance of that processing.

For example, the surface kinetics associated with the molecular self-assembly processing 102 can be controlled using one or more of a variety of techniques. Some illustrative examples of such techniques are as follows; however, generally, any technique or combination of techniques can be used to produce desired kinetic behavior of a processing fluid at a substrate surface. For instance, vibration can be imparted to a substrate during molecular self-assembly. The description above regarding the use of vibration during pre-processing 101 applies as well to the use of vibration during the molecular self-assembly processing 102. The substrate can also be rotated or translated (at a frequency much less than that of the vibration). Additionally, the chemistry fluid dynamics can be controlled to produce desired flow conditions (e.g., particular regime of turbulent or laminar flow) of chemical constituent(s) at the surface of the substrate by, for example, ensuring that a desired amount of the chemical constituent(s) is delivered to a surface of the substrate in a desired manner. A magnetic and/or electric field in the region of the substrate can also be used to enhance reaction kinetics, efficiency, and/or uniformity. Control of the surface kinetics during the molecular self-assembly processing 102 using one or more of the techniques described above can reduce the time required for the processing by promoting formation of a molecularly self-assembled layer, and can promote defect-free formation of the molecularly self-assembled layer. Each of the above-described techniques can be implemented using conventional commercial substrate processing apparatus and methods, or by modifying such substrate processing apparatus and methods in an appropriate manner as can be readily understood by one skilled in the art in view of the description herein.

As for the wet pre-processing described above, the molecular self-assembly can control fluid dynamics during the molecular self-assembly processing 102. In general, any technique or combination of techniques can be used to produce desired fluid dynamic behavior of a processing fluid. Some illustrative examples of such techniques are given following. The flow rate(s) of chemicals into the processing chamber can be controlled to affect the fluid dynamic characteristics in the chamber. The fluid dynamic characteristics affecting the substrate can also be affected by how much and which part of the substrate (e.g., the entire area of the substrate that is to be processed) is exposed to the processing fluid. Spray processing, spin processing, puddle processing, agitation and the like can be used. A magnetic and/or electric field in the region of the substrate can also be used to alter the flow dynamics of the magnetic and/or charged species. The fluid dynamics of the processing fluid can also be affected by the efficacy of a previous drying step, e.g., how free of streaks and water marks the substrate is. Appropriate control of the fluid dynamics during the molecular self-assembly processing 102 can ensure adequate delivery of chemical constituents to substrate surface(s) to promote the molecular self-assembly process.

As for the wet pre-processing described above, the molecular self-assembly can control temperature during the molecular self-assembly processing 102. The description above regarding the control of temperature during the pre-processing 101 applies as well to the control of temperature during the molecular self-assembly processing 102. Control of the process temperature during molecular self-assembly processing enables the use of temperature compensation to avoid undesirable temperature extremes that may otherwise result during an exothermic or endothermic reaction that can occur during molecular self-assembly processing.

Residue can build up on the walls of a processing chamber as the amount of processing done in the chamber increases. This residue buildup can contaminate chemistries introduced into the processing chamber and/or may increase the attraction of chemical constituents of those chemistries to the substrate walls, exacerbating the residue buildup. In one aspect of the molecular self-assembly, the negative consequences of residue buildup on the walls of a wet processing chamber used for molecular self-assembly can be reduced or eliminated by using the chamber to form a molecularly self-assembled layer on the chamber walls. The formed layer passivates the chamber walls for molecular self-assembly to be subsequently performed in the chamber. This can be done by flooding the processing chamber with a fluid having a specified chemistry that will form a molecularly self-assembled material (e.g., a self-assembled monolayer) on the walls of the processing chamber, that molecularly self-assembled material having properties that enable it to act as a passivation layer for a molecularly self-assembled material to be formed in subsequent processing. For example, the chemistry used to produce the passivation layer can be specified so that a polymeric material forms by molecular self-assembly on the chamber walls. Additionally, before performance of the subsequent molecular self-assembly for which the chamber walls are being passivated, another process can be performed to functionalize the passivation layer to inhibit any propensity of that layer to react with the chemistry used in the subsequent molecular self-assembly.

Following is a description of a particular example of creation of a passivation layer on a processing chamber using the molecular self-assembly processing 102. It is assumed that it is desired to form a primary molecularly self-assembled material on a substrate that will attach only to a hydroxyl terminated surface. The processing chamber walls can be passivated by performing processing in which a molecularly self-assembled monolayer is formed that terminates in a non-hydroxyl group, such as ammonia. Before or after the passivation, the substrate surface(s) on which it is desired to form the primary molecularly self-assembled material are functionalized so that hydroxyl groups are present on the substrate surface(s), in preparation for the processing that will form that molecularly self-assembled material.

The post-processing 103 of an embodiment finishes in some way the material formed in the molecular self-assembly processing 102. As with the pre-processing 101, the particular post-processing performed often depends on what is done in the molecular self-assembly processing 102, i.e., the characteristics of the processing performed and material(s) formed. The post-processing 103 can include one or more of wet post-processing, dry post-processing, and/or a combination of wet post-processing and dry post-processing. Generally, in an embodiment, any post-processing 103 can be used. As with other processing, the post-processing 103 can generally be performed using existing commercial substrate processing apparatus (e.g., conventional semiconductor processing apparatus).

For example, the post-processing 103 will include cleaning in which residue, contaminants and/or other unwanted material (e.g., unwanted regions of material formed in the molecular self-assembly processing 102) are removed from exposed substrate surface(s). Post-processing cleaning can be used, for instance, to get rid of unattached molecules formed on the substrate during the molecular self-assembly processing 102, such as un-bonded molecules that formed on substrate surface(s) other than surface(s) functionalized for attachment (covalent bonding) of the self-assembled molecules. Post-processing cleaning can be implemented, for example, using megasonic or ultrasonic cleaning, or spin rinsing. Post-processing cleaning is a process in which vibration can usefully be imparted to a substrate to facilitate the cleaning of the substrate.

The post-processing 103 can also include one or more processes in which the substrate is annealed or cured. Thermal annealing or curing can be used. Electron beam (e-beam) or ultraviolet radiation annealing or curing can also be used. In particular, the use of electron beam or ultraviolet radiation annealing or curing after the use of molecular self-assembly to form material on a substrate can be used in substrate processing including the use of molecular self-assembly. Annealing can be used, for example, after electrochemical deposition of a material such as copper, to accelerate grain growth and film stability. Annealing or curing may be performed in a process apparatus that is constructed for that purpose and that is different from apparatus used for other processing of a substrate, but is not so limited.

The post-processing 103 can also include vaporization. Either or both of thermal and plasma vaporization can be used. Vaporization can be performed using the same apparatus used to perform annealing or curing, as described above. For instance, after functionalizing a molecularly self-assembled material with an organo-metallic tail group, annealing can be performed until the polymer breaks down and vaporizes, bonding the metallic material to the underlying material on which the molecularly self-assembled material was formed. This can be advantageous, as opposed to forming the metallic material directly on the underlying material, because the molecularly self-assembled material can be made more selective than the metallic material, thus enabling the metallic material to more easily be formed in desired regions. This can also be used as a means of forming conformal atomic scale metallic films.

In addition to the pre-processing, molecular self-assembly and post-processing described above, other types of processing may be included under an embodiment. For example, to reduce cross-contamination of different chemicals used in different processes performed in the same chamber, an embodiment can include the performance of one or more conventional purge, neutralization and/or passivation processes. This can be particularly useful when the same processing chamber is used for a large number of processes and/or a large number of types of processing (e.g., wet pre-processing, molecular self-assembly, functionalization of molecularly self-assembled material and post-processing cleaning).

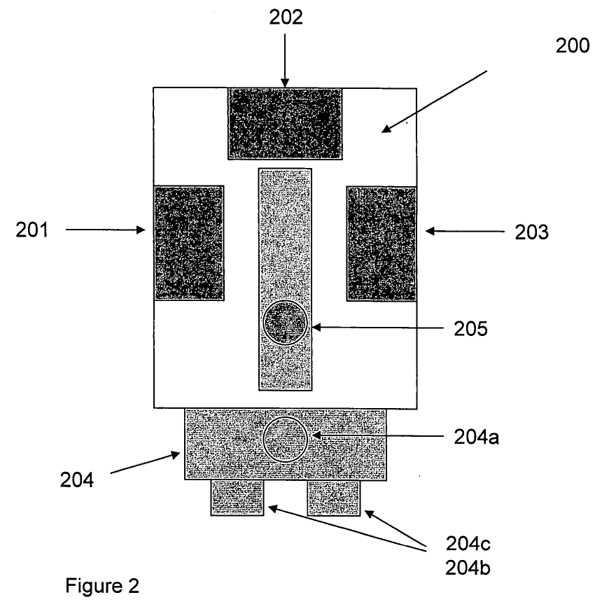

Additionally, when wet processing is used in an embodiment as part of any or all of the pre-processing 101, molecular self-assembly processing 102 and post-processing 103, the substrate may be dried after rinsing with, for example, de-ionized water, either completely or at least to a point that ensures that water marks will not be left on the substrate. Thus, when wet processing is used in an embodiment the substrate is dried when the substrate is moved from a wet processing chamber to a dry processing chamber, or from a wet processing chamber to the system interface of the system (e.g., FIGS. 2, 3, and 4) of which the wet processing chamber is part.

An embodiment can also include drying when the substrate is moved from one wet processing chamber to another. Thus, a drying process can be part of one or more of the pre-processing 101, molecular self-assembly processing 102 and post-processing 103, or a drying process may not be associated with any of the pre-processing 101, molecular self-assembly processing 102 and post-processing 103, if the drying process occurs between two of the pre-processing 101, molecular self-assembly processing 102 and post-processing 103. Any type of drying process can be used. For example, a rapid vapor drying process, such as an isopropyl alcohol (IPA) drying process (e.g., Marangoni drying), can be used. Alternatively, spin rinse drying can be used. Drying is commonly performed in the same processing chamber in which cleaning is performed but is not so limited.

Substrate processing in accordance with the molecular self-assembly of an embodiment can be performed using conventional substrate processing apparatus known to those skilled in the art of processing substrates in view of the types of substrate processing to be performed. In particular, conventional commercial substrate processing apparatus (e.g., conventional commercial semiconductor processing apparatus) can be used, with, in some cases, some modification and/or addition as appropriate to the substrate processing of an embodiment. Any such modification or addition can be effected by one of skill in the relevant art in view of the description herein.

For example, a chemical delivery system may be modified to enable delivery of chemistries that are different from, and/or in addition to, the types of chemistries that can otherwise be delivered by that apparatus. As another example, an apparatus for imparting vibration to a substrate may be added to conventional substrate processing apparatus. As still another example, an apparatus for producing a magnetic and/or electric field in the region of a substrate may be added to conventional substrate processing apparatus.

Each of the pre-processing 101, molecular self-assembly processing 102, and post-processing 103 can be implemented in a single or multiple processing modules. Additionally, each of the pre-processing 101, molecular self-assembly processing 102, and post-processing 103 can be implemented in module(s) that are entirely different from, partly different from, or the same as module(s) used to implement, in whole or in part, one or both of the other of the pre-processing 101, molecular self-assembly processing 102, and post-processing 103. As will be understood from the description herein, the number and type of modules used, as well as whether process steps are performed in the same module can depend on the particular processes performed.

FIG. 2 is a substrate processing system 200 using molecular self-assembly, under an embodiment. The substrate processing system 200 includes a pre-processing module 201, a molecular self-assembly processing module 202, and a post-processing module 203. Each of the pre-processing 101, molecular self-assembly processing 102, and post-processing 103 described above are implemented in a single module that is different from the modules used to implement the other of the pre-processing 101, molecular self-assembly processing 102, and post-processing 103, but the embodiment is not so limited. For example, any of the modules 201, 202, and 203 may include functions of the pre-processing, molecular self-assembly, and/or post-processing modules. The system 200 is not required to include at least one of each of the preceding module types; for example, a particular process flow may include only the molecular self-assembly processing module 202 and means for moving a substrate into and out of the system 200. Also, functions of all of the pre-processing, molecular self-assembly, and post-processing modules may be embedded within a single module. The modules 201, 202 and 203 can each be implemented using apparatus (in particular, conventional commercial substrate processing apparatus) as appropriate to the types of substrate processing for which the modules 201, 202 and 203 are to be used. The modules 201, 202, and 203 may be implemented with modification(s) and/or addition(s) depending on the particular characteristics of the molecular self-assembly. For example, when the molecular self-assembly is used to process semiconductor wafers, the modules 201, 202 and 203 are implemented using conventional commercial semiconductor wafer processing apparatus and methods.

Substrates enter and leave the system 200 via a system interface 204, also referred to as a factory interface 204. A single substrate can be processed at one time in the system 200 or multiple substrates can be processed at one time in a batch. The system interface 204 includes a substrate handler 204a (which can be implemented, for example, using a robot) that moves substrate(s) into and out of the system 200. To facilitate moving substrates into and out of the system 200, the system interface 204 includes a substrate load station 204b and a substrate unloading station 204c (also referred to as a wafer cassette (FOUP) load station 204b and a wafer cassette (FOUP) unload station 204c, respectively).

After substrate(s) that have been processed are removed from the system 200 and placed on the substrate unload station 204c (for eventual movement to another location) by the substrate handler 204a, new substrate(s) that have previously been placed on the substrate load station 204b are taken from the substrate load station 204b by the substrate handler 204a and moved into the system 200 for processing. The system interface 204 (including the substrate handler 204a, substrate load station 204b and substrate unload station 204c) can be implemented using conventional apparatus and methods known to those skilled in the art of processing substrates. For example, when the molecular self-assembly is used to process semiconductor wafers, the system interface 204 can be implemented using conventional apparatus and methods known to those skilled in the art of processing semiconductor wafers to enable movement of a wafer and/or a cassette of wafers into and out of the semiconductor wafer processing system. The system 200 of one or more alternative embodiments can include multiple system interfaces, each of which can be constructed and operate as described above.

Once in the system 200, a substrate handling system 205 can be used to move substrate(s) processed by the system 200 between different modules 201-203 of the system 200. Like the substrate handler 204a of the system interface 204, the substrate handling system 205 can be implemented, for example, using one or more robots. If the modules 201, 202 and 203 include both wet and dry processing modules, then the substrate handling system 205 includes at least two types of apparatus: a dry substrate handler for moving substrate(s) into and out of dry processing modules and the system interface 204 and out of a drying module, and a wet substrate handler for moving substrate(s) into and out of wet processing modules and into a drying module. The substrate handling system 205 can be implemented using apparatus and methods known to those skilled in the art of processing substrates. For example, when the molecular self-assembly is used to process semiconductor wafers, the substrate handling system 205 can be implemented using conventional apparatus and methods known to those skilled in the art of processing semiconductor wafers to enable movement of a wafer and/or a cassette of wafers between different modules of the semiconductor wafer processing system.

Other than when substrate(s) are being moved into or out of the system 200 through the system interface 204, the system 200 is sealed from the external environment. Depending on the processing to be performed by the system 200, the environment within the system 200 that is outside of the pre-processing module 201, molecular self-assembly processing module 202, and post-processing module 203 (for convenience, sometimes referred to hereinafter as the “system environment”) can be maintained at atmospheric pressure, held at a vacuum pressure, and/or pressurized (i.e., held at a pressure above atmospheric pressure). Similarly, the system environment can be maintained at the ambient temperature of the environment outside of the system 200, or at a temperature that is higher or lower than that ambient temperature.

Further, the gaseous composition of the system environment can be controlled as desired. For example, the system environment can be ambient air (typically, controlled to reduce contamination from the external environment). The system environment can also be controlled to include, in whole or in part, a specified gas or gases, e.g., in a system used to process semiconductor wafers, the system environment can be controlled to be nitrogen or an inert gas. The system environment can also be controlled to exclude a specified gas or gases, e.g., oxygen can be excluded from the system environment to reduce the occurrence of oxidation of substrate(s) (or material(s) formed thereon) processed in the system.

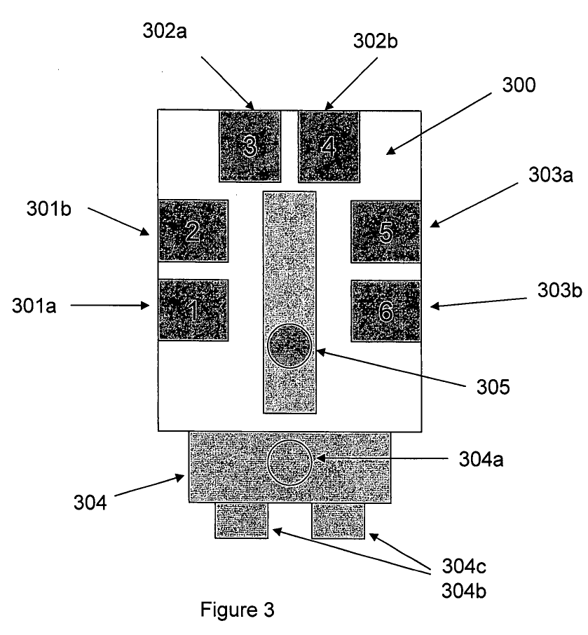

FIG. 3 is a substrate processing system 300 using molecular self-assembly, under an alternative embodiment. The system 300 includes a system interface 304. The system interface 304 of an embodiment includes but is not limited to a substrate handler 304a, substrate load station 304b and a substrate unload station 304c for moving substrate(s) into and out of the system 300. The system 300 includes a substrate handling system 305 for moving substrate(s) processed by the system 300 between different modules of the system 300. Each of the system interface 304, substrate handler 304a, substrate load station 304b, substrate unload station 304c and substrate handling system 305 can be implemented and operate as described above for the corresponding components of the system 200 (FIG. 2). Additionally, the system environment described above with respect to the system 200 applies to the system environment of the system 300.

The substrate processing system 300 includes two pre-processing modules 301a and 301b, two molecular self-assembly processing modules 302a and 302b, and two post-processing modules 303a and 303b, but is not so limited. Alternative embodiments of system 300 can include any number of each of the pre-processing modules 301a and 301b, molecular self-assembly processing modules 302a and 302b, and post-processing modules 303a and 303b.

As described above, in substrate processing according to the molecular self-assembly, pre-processing can include both wet processing and dry processing. In the system 300, the pre-processing modules 301a and 301b can be dry and wet processing modules, respectively, for performing pre-processing of substrates (e.g., pre-processing module 301a includes a plasma (dry) surface preparation module, and pre-processing module 301b includes a wet clean/surface preparation module). Any of the wet pre-processing and dry pre-processing described above can be performed in the modules 301a and 301b. The pre-processing modules 301a and 301b of various alternative embodiments can include an pre-processing processes.

The molecular self-assembly processing modules 302a and 302b can include, for example, a module 302a for forming self-assembled molecular material (e.g., self-assembly growth module) and a module 302b for performing subsequent processing that functionalizes that material (e.g., functionalization module). Any of the types of molecular self-assembly and subsequent functionalization described above can be performed in the modules 302a and 302b. The molecular self-assembly processing modules 302a and 302b of various alternative embodiments can include any self-assembly processes.

The post-processing modules 303a and 303b can include, for example, a module 303a for cleaning the substrate after forming material using molecular self-assembly (e.g., post-processing clean module) and a module 303b for annealing and/or vaporizing that material (e.g., post-processing anneal/vaporization module). Any of the types of cleaning, annealing and vaporizing described above can be performed in the modules 303a and 303b. The post-processing modules 303a and 303b of various alternative embodiments can include any post-processing processes.

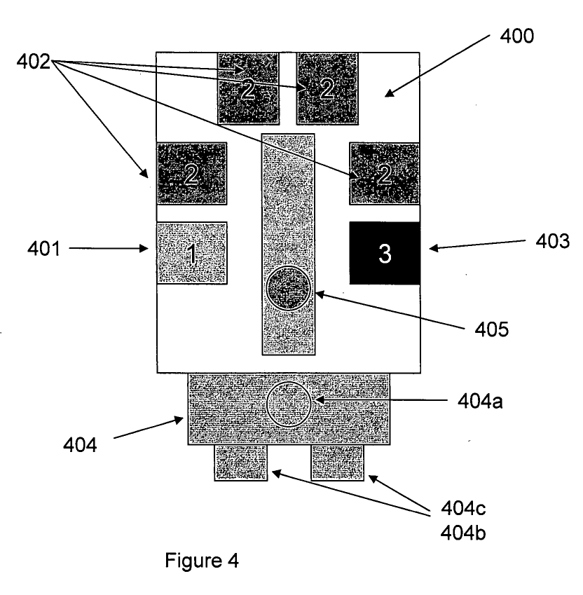

FIG. 4 is a substrate processing system 400 using molecular self-assembly, under another alternative embodiment. The substrate processing system 400 includes one pre-processing module 401 (e.g., plasma (dry) surface preparation module), four molecular self-assembly processing modules 402, and one post-processing module 403. The system 400 of alternative embodiments can include any number, type, and/or combination of modules.

The pre-processing module 401 of an embodiment can include a plasma (dry) surface preparation module, but is not so limited. However, any of the wet pre-processing and dry pre-processing described herein can be performed in the pre-processing module 401.

The molecular self-assembly processing modules 402 can include, for example, a wet clean/surface preparation module, a module for forming self-assembled molecular material (e.g., self-assembly growth module), a module for performing subsequent processing that functionalizes that material (e.g., functionalization module), and a module for cleaning the substrate after forming material using molecular self-assembly (e.g., post-processing clean module).

The post-processing module 403 can include, for example, a module 403 for annealing and/or vaporizing that material (e.g., post-processing anneal/vaporization module). Any of the types of cleaning, annealing and vaporizing described herein can be performed in the module 403.

The system 400 also includes a system interface 404, which, in turn, includes a substrate handler 404a, substrate load station 404b and a substrate unload station 404c for moving substrate(s) into and out of the system 400. The system 400 includes a substrate handling system 405 for moving substrate(s) processed by the system 400 between different modules of the system 400. Each of the system interface 404, substrate handler 404a, substrate load station 404b, substrate unload station 404c and substrate handling system 405 can be implemented and operate as described above for the corresponding components of the system 200 (FIG. 2). Additionally, the description above of the system environment for the system 200 also applies to the system environment of the system 400.

Like the substrate processing system 200 described above, the substrate processing system 400 includes three processing modules 401, 402 and 403. However, to illustrate that different types of processing steps can be performed in the same module, the module 402 of system 400 is shown four times, one for each type of processing that takes place in that module. For example, the module 402 can be used to perform the types of processing that, in system 300, take place in the four separate modules 301b, 302a, 302b and 303a, i.e., wet pre-processing, molecular self-assembly, functionalization of molecularly self-assembled material and post-processing cleaning, respectively. The system 400 can take advantage of the capability of commercial substrate processing apparatus and methods to rapidly change from one process chemistry to another in a module to facilitate the use of a single processing module for the performance of different types of process steps. In particular, in a substrate processing method including molecular self-assembly, multiple processing steps and multiple types of processing can be performed in the same processing chamber. In general, any number and combination of processes can be performed in a single processing chamber under the embodiments described herein. A spin processor coupling a chemistry dispense mechanism with substrate rotation is an example of such a processing chamber. The chemistry can be provided via a single dispense, a multi-port dispense, a spray dispense, and combinations thereof. Substrate rotation assists in uniform application of the process chemistries and can be used to dry the substrate.

In describing the substrate processing systems 200, 300 and 400, it has been assumed that a single wafer or a single batch of wafers is processed at one time. However, each of the substrate processing systems 200, 300 and 400 can be modified to include a multiplicity of each of the types of modules used to process a single wafer or single batch of wafers, i.e., multiple versions of a substrate processing system in accordance with the invention can operate in parallel as a single system. This can be desirable to improve the throughput of substrates processed by a substrate processing system. This can also be desirable to add redundancy in the substrate processing system so that system availability can be maintained even when one or more of the modules of the system are rendered non-operational for a period of time (e.g., for preventative maintenance or repair).

The molecular self-assembly systems described above are presented as examples, and systems including other numbers of processing modules can be used. Furthermore, types of processing modules other than those described above can be used. Manual loading and unloading of substrate(s) may be used in some processing systems instead of a substrate handler for moving substrate(s) into and out of the system.

The molecular self-assembly systems and methods described above can be used to form a masking layer on a dielectric region to facilitate forming of a capping layer on electrically conductive regions separated by the dielectric region, as described in the Related Applications. The capping layer inhibits electromigration in the electrically conductive regions (and, in some cases, enhances inhibition of diffusion of material from the electrically conductive regions). As an example, the MSAS of an embodiment forms a masking layer on one or more dielectric regions of a substrate, where the substrate includes (i.e., as part of, or having formed on and/or in) electrically conductive regions separated by the dielectric region(s) (such a substrate is sometimes referred to herein as an “electronic device”). The electrically conductive regions can be electrical interconnections between electrical elements (e.g., transistors, capacitors, resistors) of the electronic device.

The masking layer can be formed selectively on the dielectric region so that no or negligible masking layer material is formed on the electrically conductive regions. Alternatively, the masking layer can be formed non-selectively on both the dielectric regions and the electrically conductive regions, and masking layer material formed on the electrically conductive regions subsequently removed.

As used herein, a “capping layer” (also sometimes referred to as a “self-aligned barrier layer”) is a layer of material formed on electrically conductive regions of an electronic device (e.g., after planarization of the top of the electrically conductive regions) to inhibit electromigration in the electrically conductive regions. In particular, the capping layer inhibits electromigration in the electrically conductive regions better than a dielectric barrier layer that would otherwise be formed on the electrically conductive regions. Additionally, in some cases, a capping layer may inhibit diffusion of material from the electrically conductive regions and, in particular, may inhibit such diffusion to an extent that enables elimination, or reduction of the thickness, of a dielectric barrier layer that would otherwise be formed on the capping layer.

The capping layer can be formed selectively on the electrically conductive regions so that no or negligible capping layer material is formed on the masking layer. In particular, the material(s) and/or one or more process used to form the masking layer and/or the capping layer can be tailored to inhibit formation of capping layer material on the masking layer, thus fostering the selective formation of the capping layer on the electrically conductive regions. Alternatively, the capping layer can be formed non-selectively on both the electrically conductive regions and the masking layer, and capping layer material formed on the masking layer subsequently removed (this can be done, for example, by removing some or all of the masking layer and, with it, capping layer material formed thereon).

The MSAS of an embodiment includes forming the masking layer or capping layer with any degree of selectivity. As indicated above, “selective” formation of a material on a region or surface means that the material forms on that region or surface with better coverage of the region or surface than that with which the material forms on other region(s) or surface(s). In any embodiment of the MSAS, masking layer material formed on electrically conductive regions or capping layer material formed on the masking layer can be removed if deemed necessary or desirable. However, as discussed further below, removal of masking layer material formed on electrically conductive regions or capping layer material formed on the masking layer may not be necessary in some cases, e.g., when negligible amounts of masking layer material are formed on electrically conductive regions or negligible amounts of capping layer material are formed on the masking layer, such as may be the case when the masking layer is formed selectively on the dielectric regions or the capping layer is formed selectively on electrically conductive regions, respectively.

The MSAS of an embodiment inhibits capping layer material from being formed on the masking layer over the dielectric region (in addition to the inhibition of formation of capping layer material on or in the dielectric region, due to the presence of the masking layer on the dielectric region). Consequently, unlike previous approaches to forming a capping layer in which a layer of electrically conductive material (e.g., a cobalt alloy, nickel alloy or tungsten) is selectively deposited on electrically conductive regions, the MSAS prevents the occurrence of unacceptable current leakage between electrically conductive regions when electrically conductive material is used to form the capping layer. Since the MSAS inhibits formation of capping layer material over, on or in the dielectric region, the MSAS enables a great deal of flexibility in the selection of material(s) and/or one or more process for forming the capping layer, without regard for the selectivity of the capping layer material for the electrically conductive regions vis-a-vis the dielectric region (and, in some embodiments, without regard for the selectivity of the capping layer material for any material).

The MSAS thus enables, for example, the use of material(s) and/or process(es) and/or process regime(s) in the formation of the capping layer that would otherwise be undesirable due to a lack of sufficient selectivity. This serves to widen the material choices and/or process(es) and/or process regime(s) available for effecting other desired attributes. For example, the material and/or processes used to form the capping layer can be chosen to enhance adhesion of the capping layer to the electrically conductive regions (thus improving inhibition by the capping layer of electromigration in the electrically conductive regions). The materials and/or processes used to form the capping layer can also be chosen to produce a capping layer that does not unacceptably or undesirably increase resistance in the electrically conductive regions; for example, the capping layer can be formed without replacing any of the material of the electrically conductive regions with capping layer material having a higher resistivity. The materials and/or processes used to form the capping layer can also be chosen so that very little poisoning (undesired diffusion of constituents into and/or adverse modifications) of the electrically conductive regions occurs. Poisoning can lead to undesirable changes in electrical characteristics such as an increase in resistance of the electrically conductive regions. In yet another embodiment, the materials and/or processes used to form the capping layer can be chosen to protect the underlying electrically conductive regions from moisture containing environments, oxygen containing environments, oxidizing environments, and the like.

Additionally or alternatively, the materials and/or processes used to form the capping layer can be chosen to produce a capping layer that is sufficiently effective in inhibiting diffusion of material used to form the electrically conductive regions (e.g., copper) so that a dielectric barrier layer can be eliminated from the electronic device or, at least, reduced in thickness (with attendant decrease in capacitance and associated benefits). Further, since the masking layer inhibits formation of capping layer material in the dielectric region, the MSAS facilitates the use of porous dielectric materials that are increasingly deemed desirable for use in electronic devices. Additionally, the MSAS enables production of a thermally stable capping layer on copper so that the capping layer remains continuous and defect-free (i.e., having sufficiently few defects according to one or more criteria) under typical operating conditions of many electronic devices.

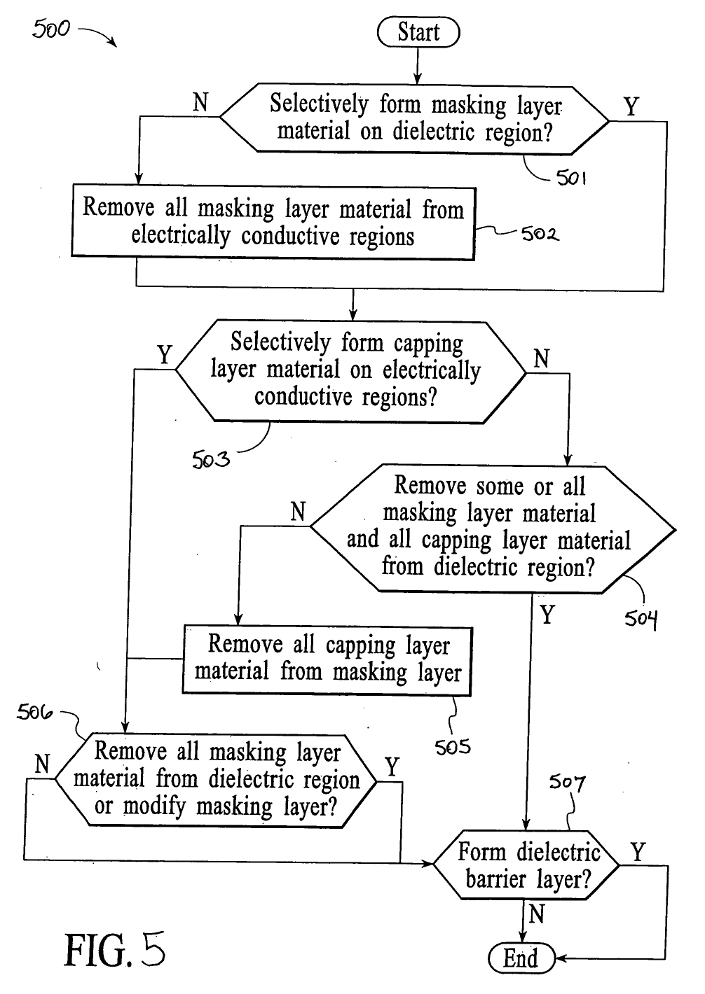

FIG. 5 is a flow diagram for forming or producing 500 a capping layer on electrically conductive regions separated by a dielectric region, under the molecular self-assembly of an embodiment. A masking layer is formed 501 and 502 on the electronic device so that the masking layer is formed on the dielectric region, but not the electrically conductive regions. After formation of the masking layer, a capping layer is formed 503, 504, 505, and 506 on the electronic device. Optionally, a dielectric barrier layer can be formed 507 on the electronic device, depending on the properties of the capping layer, as discussed further below.

The capping layer of an embodiment is formed on the electrically conductive regions but not on or in the dielectric region or the masking layer. The presence of the masking layer inhibits formation of capping layer material on or in the dielectric region that may otherwise have occurred without the masking layer. Consequently, the capping layer produced 500 forms capping layer material only on the electrically conductive regions (no or negligible capping layer material is formed over, on or in a dielectric region separating electrically conductive regions). This selective capping layer production 500 therefore reduces or eliminates unacceptable current leakage between electrically conductive regions of the substrate.

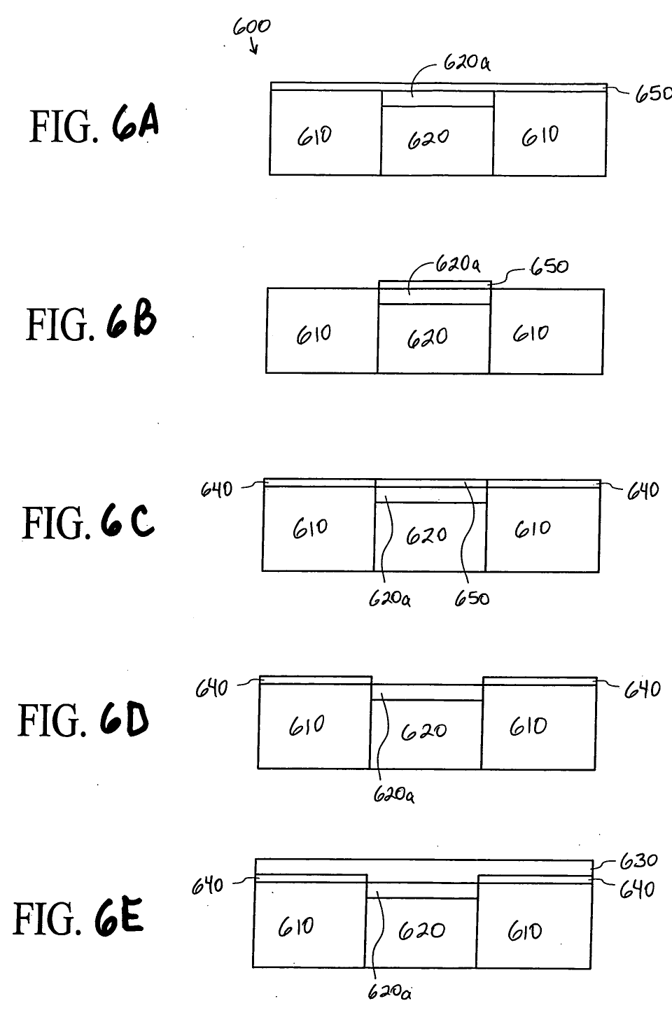

FIGS. 6A through 6E show cross-sectional views of an electronic device 600 undergoing formation of a capping layer 640 on electrically conductive regions 610 separated by a dielectric region 620, under the molecular self-assembly of an embodiment. The electrically conductive regions 610 can be interconnections between electrical elements of the electronic device, such as, for example, transistors, capacitors and resistors. The dielectric region 620 is illustrated with a hard mask layer 620a formed as a top part of the dielectric region 620, as is commonly the case in current electronic devices; however, the dielectric region 620 need not necessarily include the hard mask layer 620a. As described below, the method 500 can produce a capping layer in accordance with various alternative embodiments not shown. In particular, due to imperfect selectivity or non-selectivity of the formation of the masking layer 650, masking layer material can be formed on the electrically conductive regions 610 that is subsequently removed prior to forming the capping layer 640. However, the formation of the masking layer 650 may also be accomplished with greater selectivity i) so that no masking layer material is formed on the electrically conductive regions 610 (in that case, the intermediate structure shown in FIG. 6A would not occur) or ii) so that a negligible amount of masking layer material is formed on the electrically conductive regions 610 that need not necessarily be removed from the electrically conductive regions 610 (in that case, the intermediate structure shown in FIG. 6B would not occur and the subsequently formed structures shown in further figures would include the negligible amount of masking layer material formed on the electrically conductive regions 610).

Generally, a masking layer 650 is formed non-selectively on both the dielectric region 620 and the electrically conductive regions 610. The masking layer material is removed from the electrically conductive regions 610, and capping layer material is formed selectively on the electrically conductive regions 610. The masking layer material is removed from the dielectric region 620, and a dielectric barrier layer 630 is formed over the capping layer 640 and dielectric region 620.

Prior to forming a masking layer in accordance with the invention, the exposed surfaces of the electrically conductive regions and the exposed surface of the dielectric region are prepared for processing in accordance with the invention. This surface preparation includes at least one or more cleaning steps (e.g., a deionized water rinse and/or any of a variety of other well-known surface cleaning step(s)) to remove contaminants left from previous processing. In particular, a low-pH solution chemistry can be used to remove copper oxides and a high pH solution chemistry can be used to remove post CMP residue(s).

The surface preparation can include other processing steps as well. For example, the exposed surfaces of the electrically conductive regions and/or the exposed surface of the dielectric region can be functionalized to facilitate selective formation of the masking layer. In particular, the surface of the dielectric region can be functionalized to promote formation of the masking layer and the exposed surfaces of the electrically conductive regions can be functionalized to inhibit formation of the masking layer. Similarly, the exposed surfaces of the electrically conductive regions and/or the exposed surface of the dielectric region can also be functionalized to facilitate selective formation of the capping layer. In particular, the surface of the dielectric region can be functionalized to inhibit formation of the capping layer (though the use of a masking layer in accordance with the molecular self-assembly described herein may render this unnecessary or, at least, of greatly reduced importance) and the exposed surfaces of the electrically conductive regions can be functionalized to promote adhesion of the capping layer.

In general, the particular manner in which the surfaces of the electrically conductive regions and/or the surface of the dielectric region are functionalized depends on the nature of the materials used to form the electrically conductive regions, the dielectric region and the masking layer, and the desired properties to be produced (e.g., passivation, promotion of material formation). For example, a dielectric region formed of a silicon dioxide-based dielectric material can be functionalized to produce a large number of hydroxyl groups at the surface of the dielectric region to which a self-assembled monolayer has an affinity for attachment, thus promoting formation of the masking layer on the dielectric region. Additionally, a molecule used to form a molecularly self-assembled layer can be established to include a head group that covalently bonds with an exposed hydroxyl group of the material used to form a dielectric region.

With reference to FIG. 5, a masking layer is formed 501 and 502 on an electronic device so that the masking layer is formed on a dielectric region of the electronic device, but not on the electrically conductive regions of the electronic device that are separated by the dielectric region. The masking layer can be formed 501 selectively on the dielectric region or the masking layer can be formed non-selectively on both the dielectric region and the electrically conductive regions. Selective formation of a masking layer on a dielectric region encompasses negligible formation of masking layer material on the electrically conductive regions, i.e., masking layer material coverage that does not impair performance of a method according to the molecular self-assembly or the functionality of an electronic device produced using molecular self-assembly.

Non-selective formation of a masking layer on both the dielectric region and the electrically conductive regions encompasses formation of the masking layer with no preference for the dielectric region or electrically conductive regions, with some degree of preference for the electrically conductive regions, or with preference for the dielectric region that is inadequate to result in the formation of no or negligible masking layer material on the electrically conductive regions. When the masking layer is formed non-selectively on the dielectric region and the electrically conductive regions, all masking layer material formed on the electrically conductive regions is subsequently removed 502. Removal of all masking layer material formed on the electrically conductive regions encompasses leaving negligible masking layer material formed on the electrically conductive regions. Referring again to the electronic device 600, non-selective formation of a masking layer 650 on both the dielectric region 620 and the electrically conductive regions 610 is followed by removal of all masking layer material formed on the electrically conductive regions 610, leaving the masking layer 650 formed only on the dielectric region 620.

In general, the masking layer can be formed using any number, type, and/or combination of materials and processes that form a masking layer. The masking layer can be formed using either wet processing (e.g., immersion of a substrate in a chemical bath, spraying or spinning of chemical fluid on to a substrate) or dry processing (e.g., vapor deposition). If wet processing is used, a rinsing process may be used afterwards to clean the electronic device, which is then followed by a drying process. Additionally, if wet processing is used, vibration of specified amplitude and/or frequency (e.g., high frequency vibration, such as ultrasonic or megasonic vibration) can be imparted to the electronic device during the processing to facilitate (e.g., speed up) the processing. The masking layer can be deposited or grown on the dielectric region. The masking layer can also be formed by stamping.

The masking layer of an embodiment is formed comprising an electrically insulative (effectively non-conductive) material, since the masking layer is formed in regions that, in the finished electronic device, are electrically non-conductive. However, in embodiments in which the masking layer is completely removed from the electronic device (e.g., FIG. 6D), the masking layer can be formed of an electrically conductive or semiconductor material.

After formation of the masking layer, the masking layer can be functionalized or otherwise modified (e.g., chemically, thermally and/or photo-chemically modified) in a desired manner to produce desired properties (e.g., to produce a desired propensity for formation on the masking layer of material to subsequently be formed on the electronic device, such as a capping layer or a dielectric barrier layer, or to enable some or all of the masking layer to be removed after formation of the capping layer so that capping layer material formed on the masking layer can be removed).

The masking layer can be, for example, a molecularly self-assembled layer, which can be formed as a monolayer (SAM) or a multilayer, and can be formed of organic and/or inorganic material. A molecularly self-assembled layer can be produced by forming (e.g., depositing or growing) additional material on the surface of the dielectric region, or by chemically activating or modifying the material of the dielectric region to produce a new distinct layer of material. The ability to tailor the molecule type, head group, terminal group and/or chain length of a molecularly self-assembled layer advantageously provides flexibility in establishing the characteristics of a masking layer, which can be used to produce desired masking layer properties, as described herein. The masking layer can also be, for example, a layer formed from any class of materials known to form with controlled film thickness, such as, for instance, multi-layer polyelectrolytes. The masking layer can also be, for example, a layer formed on the surface of the dielectric region through the catalytic growth of inorganic or organic materials. The masking layer can also be, for example, a layer formed from dendrimers, hyper-branched polymers, or block co-polymers. The masking layer can also be, for example, an ionic or electrochemically-enhanced self-assembled multilayer or monolayer.

The characteristics of a masking layer formed using the molecular self-assembly can be established to produce desired properties of the masking layer. For example, the type of molecule(s) used to form a molecularly self-assembled layer can be chosen, and the characteristics of the molecule, such as the head group, terminal group and/or length, can be established to produce desired properties of the molecularly self-assembled layer. The particular manner in which the characteristics of a masking layer are tailored include for example one or more of the properties of the dielectric region, the necessity or desirability of avoiding formation of masking layer material on the electrically conductive regions, the characteristics of the materials and/or processes used to form the capping layer, and/or the characteristics of the materials and/or processes used to subsequently form material on the masking layer, but are not so limited.

As further examples, the materials and/or processes used to form the masking layer can be selected to facilitate achievement of one or more of the following properties: high selectivity for the dielectric region; high selectivity for a SiCOH dielectric material; high selectivity for a silicon-based hard mask layer; adheres to a dielectric barrier layer (commonly formed of a composition including silicon together with carbon and/or nitrogen, i.e., SiCₓ, SiNₓ, SiCₓN_{y}) or other material to be subsequently formed on the masking layer; provides a good barrier to diffusion of the capping layer material (e.g., a cobalt alloy, such as a cobalt-tungsten-phosphorous alloy), both during production of the capping layer and during operation of the finished electronic device (if the masking layer is left as part of the finished electronic device); facilitates removal of some or all of the masking layer (and, with it, any capping layer material that may have been formed thereon), e.g., that produce a terminal group of a molecularly self-assembled layer that can be cleaved from the rest of the molecularly self-assembled layer or that produce an organic backbone of a molecularly self-assembled layer that can be broken down and removed; produces a continuous and defect-free layer and that, if to be left as part of the electronic device, remains so even when subjected to the thermal and chemical environment associated with further processing to produce the electronic device and/or operation of the finished electronic device; enables rapid (e.g., less than about 60 seconds) production of a masking layer.

As one example, silane-based materials can be used to form a masking layer in one or more embodiments of the molecular self-assembly. For example, it is known that a silane with one or more hydrolysable substituents of the general formula RₙSiX₄₋ₙ (where R can be, for example, alkyl, substituted alkyl, aryl or substituted aryl, and X can be, for example, halo, alkoxy, aryloxy or amino) can form a SAM that can exhibit strong covalent or non-covalent attachment to particular surfaces. Typically, SAM surface attachment is enhanced on a surface having a relatively high density of acidic functionalities such as hydroxyl or hydroxysilyl groups. Silicon-based material surfaces such as SiO₂, SiOH and SiOC surfaces possess relatively high densities of hydroxyl groups. Thus, a silane-based SAM can be expected to form with greater adhesion to a surface of a silicon-based material (of which a dielectric region is commonly formed) than to a surface of a metallic material (of which electrically conductive regions are commonly formed).

Furthermore, a silane-based SAM can also be tailored to reversibly adhere to a surface depending on the nature and substitution of a silane precursor material. For example, silicon-based SAM precursors with a single hydrolysable substituent (e.g., of the general formula R¹R²R³SiX) are known to produce a SAM that can be formed on, and reversibly detached from, a functionalized surface (e.g., a surface having a relatively high density of acidic functionalities) under specific reaction conditions. Silanization of surfaces is discussed in detail in, for example, Silanes, Surfaces and Interfaces (Chemically Modified Surfaces, Vol. 1), edited by Donald E. Leyden, Gordon & Breach Science Publishers, 1986.

With reference to FIG. 5, subsequent to forming 501 and 502 the masking layer the molecular self-assembly of an embodiment forms 503, 504, 505, and 506 a capping layer on the electronic device. The capping layer is formed on the electrically conductive regions, but not on or in the masking layer and/or the dielectric region. The capping layer can be formed 503 selectively on the electrically conductive regions or the capping layer can be formed non-selectively on both the masking layer and the electrically conductive regions. Selective formation of a capping layer on electrically conductive regions encompasses negligible formation of capping layer material on or in the masking layer and/or dielectric region. Non-selective formation of a capping layer on both the masking layer and the electrically conductive regions encompasses formation of the capping layer with no preference for the electrically conductive regions or masking layer, with some degree of preference for the masking layer, or with preference for the electrically conductive regions that is inadequate to result in the formation of no or negligible capping layer material on or in the masking layer and/or dielectric region.

When the capping layer is formed non-selectively on the masking layer and the electrically conductive regions, all capping layer material formed on the masking layer is subsequently removed 504 and 505. Referring again to FIG. 6C, the electronic device 600 includes selective formation of a capping layer 640 on the electrically conductive regions 610; non-selective formation of a capping layer on the masking layer and the electrically conductive regions, followed by removal of all capping layer material formed on the masking layer is further described in the Related Applications.

The capping layer is generally formed using any of a number, type, and/or combination of materials and processes as appropriate to the electronic device (e.g., that inhibits electromigration in electrically conductive regions on which the capping layer is formed, that inhibits diffusion of material from electrically conductive regions on which the capping layer is formed). The capping layer can be formed of an electrically conductive, semiconductor or electrically insulative (effectively non-conductive) material. For example, materials (e.g., cobalt alloys, such as an alloy of cobalt, tungsten and phosphorous or an alloy of cobalt and boron; nickel alloys, such as an alloy of nickel, molybdenum and phosphorous; tungsten; tantalum; tantalum nitride, etc.) and processes (e.g., electroless deposition; chemical vapor deposition; physical vapor deposition (sputtering); atomic layer deposition; etc.) that have previously been used to selectively deposit a capping layer on electrically conductive regions of a semiconductor device can be used. The capping layer can be functionalized but is not so limited.

The presence of the masking layer prevents formation of capping layer material on or in (through diffusion) the dielectric region, thus enforcing good selectivity of the capping layer material for the electrically conductive regions compared with the dielectric region regardless of the selectivity otherwise associated with the material(s) and process(es) used to form the capping layer. Thus, the molecular self-assembly described herein provides increased flexibility in the materials and processes that can be used to form the capping layer. For example, the molecular self-assembly enables use of materials and processes for depositing an electrically conductive material to form a capping layer that have previously been inadequate to form a capping layer without producing unacceptable current leakage between electrically conductive regions, but that are effective in inhibiting electromigration because of good adhesion to electrically conductive regions.

Additionally, since the presence of the masking layer enables production of a capping layer by forming additional material on an electrically region, there is no need to create a capping layer by chemically modifying a top part of the electrically conductive region. Thus, the undesirable increase in resistance in the electrically conductive region that is associated with creation of a capping layer in that manner is avoided using the molecular self-assembly described herein.

As described above with reference to FIGS. 5 and 6, when the capping layer is formed non-selectively on both the masking layer and the electrically conductive regions, all capping layer material formed on the masking layer is subsequently removed 504 and 505 so that no (or negligible) capping layer material is present over the dielectric region. This reduces or eliminates the possibility of current leakage between the electrically conductive regions when an electrically conductive material is used to form the capping layer. Removal of the capping layer includes removing 505 just the capping layer material from the masking layer, or removing 504 a portion (e.g., a top part on which the capping layer material is formed) or all of the masking layer together with the capping layer material formed thereon.

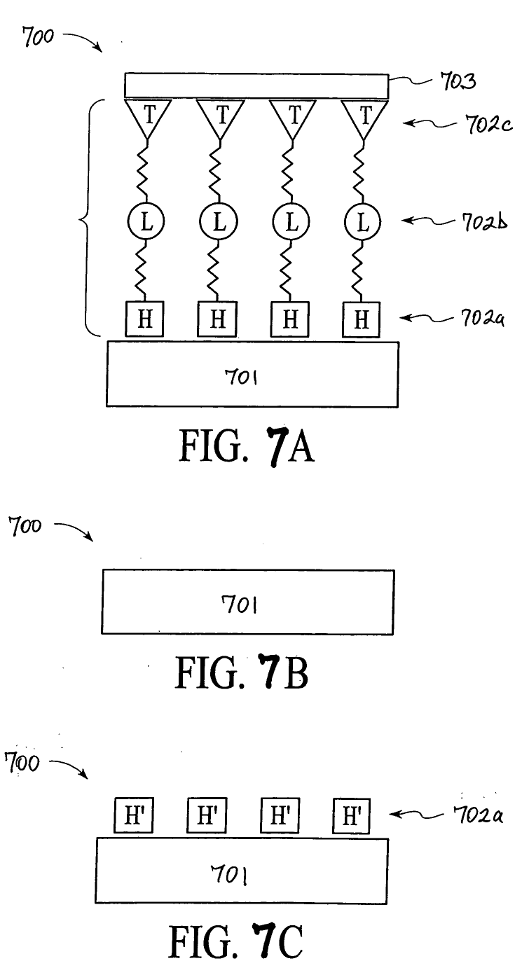

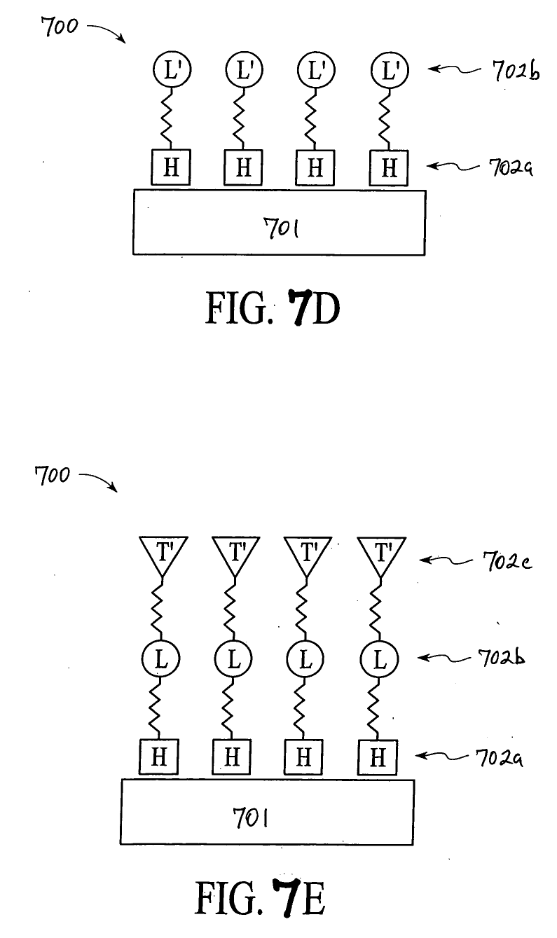

FIG. 7A shows a cross-section of a structure 700 including a dielectric region 701 on which a masking layer 702 and a capping layer 703 are formed, using the molecular self-assembly of an embodiment. The masking layer 702 is a self-assembled monolayer (SAM) but is not so limited. The SAM includes one or more of the following, but is not so limited: a head group 702a formed on the dielectric region 701; a linking group 702b connected to the head group 702a; a terminal group 702c connected to the linking group 702b, on which one or more other materials can be formed.

FIGS. 7B through 7E show additional cross-sections of the structure 700 during further processing to remove the capping layer 703, under an embodiment. Each of FIGS. 7B through 7E illustrates a different approach to effect removal of a capping layer from a dielectric region. In FIG. 7B, the entire masking layer 702 is removed from the dielectric region 701; as a consequence of removing the masking layer 702, the capping layer 703 is also removed from over the dielectric region 701.

In FIG. 7C, the head group 702a of the masking layer 702 is cleaved, removing part of the head group 702a, all of the linking group 702b and all of the terminal group 702c of the masking layer 702, together with the capping layer 703 formed on the masking layer 702. The part of the head group 702a remaining on the dielectric region 701 is designated as “H′” (H prime) to indicate difference from the unmodified head group 702a of FIG. 7A.

In FIG. 7D the linking group 702b of the masking layer 702 is cleaved, removing part of the linking group 702b and all of the terminal group 702c of the masking layer 702, together with the capping layer 703 formed on the masking layer 702. The part of the linking group 702b remaining on the dielectric region 701 is designated as “L′” (L prime) to indicate difference from the unmodified linking group 702b of FIG. 7A.

In FIG. 7E, the terminal group 702c of the masking layer 702 is cleaved, removing part of the terminal group 702c of the masking layer 702, together with the capping layer 703 formed on the masking layer 702. The part of the terminal group 702c remaining on the dielectric region 701 is designated as “T′” (T prime) to indicate difference from the unmodified terminal group 702c of FIG. 7A.

Other processes (not shown) can be used to effect removal of a capping layer from over a dielectric region, and the molecular self-assembly of alternative embodiments include these alternative processes. For example, in the structure 700, the bond between the head group 702a and the linking group 702b can be broken, resulting in the removal of the linking group 702b and the terminal group 702c of the masking layer 702, together with the capping layer 703 formed on the masking layer 702.

Alternatively, the bond between the linking group 702b and the terminal group 702c can be broken, resulting in the removal of the terminal group 702c of the masking layer 702, together with the capping layer 703 formed on the masking layer 702.

In yet another alternative process, the capping layer 703 may be removed from the masking layer 702 without affecting the structure of the masking layer 702, i.e., so that the terminal group 702c, the linking group 702b and the head group 702a are not cleaved and the bonds there between are not broken. Additionally, two or more of the above-described processes can be combined; this may for example increase the likelihood that the capping layer 702 is adequately removed from over the dielectric region 701. Furthermore, in any of the processes described above in which at least part of the masking layer 702 remains on the dielectric region 701 after removal of the capping layer 703, the exposed part of the masking layer 702 can be functionalized to produce desired characteristic(s) (this is true for any type of masking layer in accordance with the molecular self-assembly, not only the masking layer 702).

Referring again to FIG. 5, when capping layer material is removed 504 and 505 from the masking layer, the removal 504 and 505 under the molecular self-assembly of an embodiment includes subsequent removal 506 of all of the masking layer or modification of the masking layer (i.e., removing some and/or functionalizing). Removing 506 all of, or modifying, the masking layer may be used to produce a surface (i.e., an exposed surface of the masking layer or the dielectric region) having particular characteristics (e.g., good propensity for adhesion to a dielectric barrier layer subsequently to be formed on the masking layer). When first removing the capping layer, then removing or modifying the masking layer, the process of an embodiment removes some or all of the masking layer (and/or to functionalize the masking layer) after removing the capping layer (rather than together with removal of the capping layer) for one or more of a variety of reasons. Any of a variety of processes can be used to remove masking layer material from the dielectric region. Similarly, any of a variety of processes can be used to functionalize a masking layer. The particular process or processes used in an embodiment to remove masking layer material from the dielectric region and/or to functionalize the masking layer can depend, in particular, on the characteristics of the masking layer material, and may also depend on the material used to form the dielectric region.

A dielectric barrier layer can also be formed 507 on the electronic device or not, depending on the properties of the capping layer. FIG. 6E shows formation of a dielectric barrier layer 630 on the electronic device 600. If a dielectric barrier layer is formed on the electronic device, such formation can be accomplished using any type, number, and/or combination of materials and/or processes.

When the capping layer is formed of a material that provides good inhibition of diffusion of the electrically conductive material into adjacent material of the electronic device while still providing other required properties of the capping layer, it is possible to eliminate the dielectric barrier layer from the electronic device or, at least, reduce the thickness of the dielectric barrier layer. The molecular self-assembly of an embodiment forms a capping layer so that diffusion of material from the electrically conductive regions into adjacent regions is inhibited with sufficient effectiveness that the dielectric barrier layer can be formed with a smaller thickness than would be the case if the capping layer was not present. The molecular self-assembly of other embodiments forms a capping layer so that diffusion of material from the electrically conductive regions into adjacent regions is inhibited with sufficient effectiveness that a dielectric barrier layer need not be formed. Eliminating the dielectric barrier layer or reducing the thickness of the dielectric barrier layer reduces capacitance, which can decrease the power consumption and/or increase speed of operation of the electronic device. By using a masking layer on the dielectric region to minimize or eliminate selectivity as an important consideration in choosing materials and/or processes for forming the capping layer, the molecular self-assembly enables formation of a capping layer that provides adequate inhibition of electromigration and a good barrier to diffusion of electrically conductive material. This enables elimination or reduction in thickness of a conventional dielectric barrier layer. The capping layer can also be optimized to resist against any deleterious effects associated with subsequent exposure to moisture containing environments, oxygen containing environments, oxidizing environments, and the like.

The molecular self-assembly of an embodiment includes a system comprising at least one of: at least one interface configured to receive at least one substrate; a number of modules coupled to the interface, the modules including one or more of at least one pre-processing module, at least one molecular self-assembly processing module, and at least one post-processing module, wherein each module contains at least one of a number of different processes as appropriate to processes contained in at least one other module, wherein processing of the substrate using the modules includes forming a masking layer on at least one dielectric region of the substrate and forming a capping layer (typically via an electroless deposition module) on at least one electrically conductive region of the substrate; and at least one handler coupled to the interface and configured to move the substrate between the interface and the modules.

The molecular self-assembly of an embodiment includes a system comprising at least one of at least one interface configured to receive at least one substrate, at least one module coupled to the interface, the at least one module including at least one molecular self-assembly processing module, and at least one handler coupled to the interface and configured to move the substrate between the interface and the at least one module.

The system of an embodiment further comprises processing the at least one substrate using the at least one module, wherein the processing includes forming a masking layer on at least one dielectric region of the substrate and forming a capping layer on at least one electrically conductive region of the substrate.

Forming the masking layer of an embodiment comprises selectively forming a molecularly self-assembled layer on the dielectric region.

Forming the masking layer of an embodiment comprises forming masking layer material on the dielectric region and the electrically conductive region and removing the masking layer material from the electrically conductive region.

Forming the capping layer of an embodiment comprises selectively forming capping layer material on the electrically conductive region.

The masking layer of an embodiment inhibits capping layer formation on the dielectric region and generates a selective capping layer.

The at least one module of an embodiment includes at least one other module selected from at least one of a pre-processing module and a post-processing module.

The at least one module of an embodiment includes a plurality of modules, wherein each module of the plurality of modules includes at least one of a plurality of different processes as appropriate to processes contained in at least one other of the plurality of modules.

The system of an embodiment further comprises forming a dielectric barrier layer over the electrically conductive region and the dielectric region after forming the masking layer and the capping layer. The dielectric barrier layer of an embodiment covers at least one of the capping layer and the masking layer.

The system of an embodiment further comprises removing the masking layer after forming the capping layer. The system of an embodiment further comprises forming a dielectric barrier layer over the electrically conductive region and the dielectric region after forming the masking layer and the capping layer. The dielectric barrier layer of an embodiment covers at least one of the capping layer and the dielectric region.

Forming masking layer material of an embodiment comprises forming a molecularly self-assembled layer on the dielectric region and the electrically conductive regions.

Forming the capping layer of an embodiment comprises forming capping layer material on the masking layer and the electrically conductive region and removing capping layer material formed on the masking layer.

The at least one module of an embodiment includes at least one of wet processing modules, dry processing modules, and treatment modules. The wet processing modules of an embodiment include at least one of clean modules, rinse modules, dry modules, electrolesss deposition modules, and electrochemical deposition modules. The dry processing modules of an embodiment include plasma processing modules. The treatment modules of an embodiment include at least one of annealing modules, vaporization modules, ultraviolet (UV) treatment modules, and e-beam treatment modules.

The substrate of an embodiment includes one or more of silicon, glass, plastic, semiconductors, and wafers.

The system of an embodiment further comprises at least one controller coupled to control an environment, wherein the environment includes at least one of an internal environment that is internal to the at least one module and an external environment that is external to the at least one module, wherein the controller controls at least one of temperature, pressure, and composition of the environment.

The controller of an embodiment controls the pressure of the environment at one or more pre-specified pressures, wherein the pre-specified pressures include atmospheric pressure, at least one pressure below atmospheric pressure, and at least one pressure above atmospheric pressure.

The controller of an embodiment controls the temperature of the environment at one or more pre-specified temperatures.

The controller of an embodiment controls the composition of the environment to include one or more pre-specified gases at one or more pre-specified compositions.

The molecular self-assembly of an embodiment includes a method, the method comprising producing a capping layer on electrically conductive regions of a device that are separated by a dielectric region of the device. The device may include an electronic device. The method of an embodiment comprises at least one of forming a masking layer on the dielectric region but, not on the electrically conductive regions, and forming a capping layer on at least the electrically conductive regions. The capping layer is formed subsequent to and/or simultaneous with the masking layer in an embodiment.

Forming a masking layer of an embodiment comprises selectively forming masking layer material on the dielectric region. Selectively forming masking layer material of an embodiment comprises selectively forming a molecularly self-assembled layer on the dielectric region.

Forming a masking layer of an embodiment comprises at least one of forming masking layer material on the dielectric region and the electrically conductive regions, and removing masking layer material from the electrically conductive regions so that no or negligible masking layer material remains on the electrically conductive regions.

Forming a capping layer of an embodiment comprises selectively forming capping layer material on the electrically conductive regions.

After formation of the masking layer and the capping layer of an embodiment, the method further comprises forming a dielectric barrier layer over the electrically conductive regions and the dielectric region.

Forming a capping layer of an embodiment comprises forming the capping layer so that the capping layer inhibits diffusion of material from the electrically conductive regions into adjacent regions with sufficient effectiveness that the dielectric barrier layer can be formed with a smaller thickness than would be the case if the capping layer was not present.

Forming a capping layer of an embodiment comprises forming the capping layer so that the capping layer inhibits diffusion of material from the electrically conductive regions into adjacent regions with sufficient effectiveness that a dielectric barrier layer need not be formed over the electrically conductive regions and the dielectric region.

After formation of the capping layer of an embodiment, the method further comprises removing the masking layer.

Subsequent to and/or simultaneous with formation of the masking layer and the capping layer of an embodiment, the method further comprises forming a dielectric barrier layer over the electrically conductive regions and the dielectric region.

Forming a capping layer of an embodiment comprises forming the capping layer so that the capping layer inhibits diffusion of material from the electrically conductive regions into adjacent regions with sufficient effectiveness that the dielectric barrier layer can be formed with a smaller thickness than would be the case if the capping layer was not present.

Forming a capping layer of an embodiment comprises forming the capping layer so that the capping layer inhibits diffusion of material from the electrically conductive regions into adjacent regions with sufficient effectiveness that a dielectric barrier layer need not be formed over the electrically conductive regions and the dielectric region.

Forming masking layer material of an embodiment comprises forming a molecularly self-assembled layer on the dielectric region and the electrically conductive regions.

Forming a capping layer of an embodiment comprises selectively forming capping layer material on the electrically conductive regions.

Forming a capping layer of an embodiment comprises at least one of forming capping layer material on the masking layer and the electrically conductive regions, removing capping layer material formed on the masking layer so that no or negligible capping layer material remains formed over the dielectric region between the electrically conductive regions. Removing capping layer material formed on the masking layer of an embodiment comprises removing some or substantially all the masking layer, thereby removing capping layer material formed on the masking layer. Removing capping layer material formed on the masking layer comprises removing capping layer material such that no or negligible masking layer material is removed.

The method of an embodiment further comprises, subsequent to and/or simultaneous with formation of the capping layer, removing the masking layer.

The method of an embodiment further comprises, subsequent to and/or simultaneous with formation of the masking layer and the capping layer, forming a dielectric barrier layer over the electrically conductive regions and the dielectric region. Forming a capping layer of an embodiment comprises forming the capping layer so that the capping layer inhibits diffusion of material from the electrically conductive regions into adjacent regions with sufficient effectiveness that the dielectric barrier layer can be formed with a smaller thickness than would be the case if the capping layer was not present.

Forming a capping layer of an embodiment comprises forming the capping layer so that the capping layer inhibits diffusion of material from the electrically conductive regions into adjacent regions with sufficient effectiveness that a dielectric barrier layer need not be formed over the electrically conductive regions and the dielectric region.

The method of an embodiment further comprises, prior to formation of the masking layer, processing exposed surfaces of the electrically conductive regions and the exposed surface of the dielectric region in a specified manner. Processing exposed surfaces of an embodiment comprises cleaning exposed surfaces of the electrically conductive regions and the exposed surface of the dielectric region. Processing exposed surfaces of an embodiment comprises functionalizing exposed surfaces of the electrically conductive regions and/or the exposed surface of the dielectric region.

The masking layer of an embodiment comprises a silane-based material.

The capping layer of an embodiment comprises an electrically conductive material.

The capping layer of an embodiment comprises a cobalt alloy.

The capping layer of an embodiment comprises a nickel alloy.

The capping layer of an embodiment comprises tungsten.

The capping layer of an embodiment comprises tantalum.

The capping layer of an embodiment comprises tantalum nitride.

Forming a capping layer of an embodiment comprises forming the capping layer using electroless deposition.

Forming a capping layer of an embodiment comprises forming the capping layer using chemical vapor deposition.

Forming a capping layer of an embodiment comprises forming the capping layer using physical vapor deposition.

Forming a capping layer of an embodiment comprises forming the capping layer using atomic layer deposition.

The capping layer of an embodiment comprises an electrically insulative material.

The dielectric region of an embodiment comprises a porous dielectric material. The dielectric region of an embodiment further comprises a hard mask layer formed on the porous dielectric material.

The dielectric region of an embodiment comprises a hard mask layer formed on a dielectric material.

The device of an embodiment is a semiconductor device.

The molecular self-assembly of an embodiment includes a device, comprising at least one of first and second electrically conductive regions. The device may include an electronic device. The device of an embodiment includes one or more of a dielectric region separating the first and second electrically conductive regions, a masking layer or part of a masking layer formed on the dielectric region, but not on the electrically conductive regions, and a capping layer formed on at least the electrically conductive regions.

The masking layer of an embodiment comprises a molecularly self-assembled layer.

The masking layer of an embodiment comprises a silane-based material.

The device of an embodiment further comprises a dielectric barrier layer formed over the capping layer and the masking layer or part of masking layer. The capping layer of an embodiment inhibits diffusion of material from the electrically conductive regions into adjacent regions with sufficient effectiveness that the dielectric barrier layer can be formed with a smaller thickness than would be the case if the capping layer was not present.

The capping layer of an embodiment inhibits diffusion of material from the electrically conductive regions into adjacent regions with sufficient effectiveness that a dielectric barrier layer need not be formed over the electrically conductive regions and the dielectric region.

The capping layer of an embodiment comprises an electrically conductive material.

The capping layer of an embodiment comprises a cobalt alloy.

The capping layer of an embodiment comprises a nickel alloy.

The capping layer of an embodiment comprises tungsten.

The capping layer of an embodiment comprises tantalum.

The capping layer of an embodiment comprises tantalum nitride.

The capping layer of an embodiment comprises an electrically insulative material.

The dielectric region comprises a porous dielectric material. The dielectric region of an embodiment further comprises a hard mask layer formed on the porous dielectric material.

The dielectric region of an embodiment further comprises a hard mask layer formed on a dielectric material of which the dielectric region is comprised.

The electronic device of an embodiment is a semiconductor device.

The molecular self-assembly of an embodiment includes a device, comprising at least one of first and second electrically conductive regions. The device may include an electronic device. The device comprises at least one of a dielectric region separating the first and second electrically conductive regions, and a capping layer formed on the electrically conductive regions. Formation of the capping layer of an embodiment includes one of more of forming a masking layer on the dielectric region, but not on the electrically conductive regions, and, after formation of the masking layer, forming the capping layer on at least the electrically conductive regions. The presence of the masking layer during formation of the capping layer results in no or negligible capping layer material being formed on, in or over the dielectric region, such that unacceptable current leakage between the first and second electrically conductive regions cannot occur during operation of the electronic device.

The device of an embodiment further comprises a dielectric barrier layer formed over the capping layer. The capping layer of an embodiment is formed so that the capping layer inhibits diffusion of material from the electrically conductive regions into adjacent regions with sufficient effectiveness that the dielectric barrier layer can be formed with a smaller thickness than would be the case if the capping layer was not present.

The capping layer of an embodiment is formed so that the capping layer inhibits diffusion of material from the electrically conductive regions into adjacent regions with sufficient effectiveness that a dielectric barrier layer need not be formed over the electrically conductive regions and the dielectric region.

The capping layer of an embodiment comprises an electrically conductive material.

The capping layer of an embodiment comprises a cobalt alloy.

The capping layer of an embodiment comprises a nickel alloy.

The capping layer of an embodiment comprises tungsten.

The capping layer of an embodiment comprises tantalum.

The capping layer of an embodiment comprises tantalum nitride.

The capping layer of an embodiment comprises an electrically insulative material.

The dielectric region of an embodiment comprises a porous dielectric material.

The dielectric region of an embodiment further comprises a hard mask layer formed on the porous dielectric material.

The dielectric region of an embodiment further comprises a hard mask layer formed on a dielectric material of which the dielectric region is comprised.

The device of an embodiment is a semiconductor device.

The molecular self-assembly of an embodiment includes an electronic device, comprising at least one of first and second electrically conductive regions, a dielectric region separating the first and second electrically conductive regions, and a capping layer formed on the electrically conductive regions, wherein no or negligible capping layer material is formed on, in or over the dielectric region, such that unacceptable current leakage between the first and second electrically conductive regions cannot occur during operation of the electronic device.

Aspects of the molecular self-assembly systems and methods described herein may be implemented as functionality programmed into any of a variety of circuitry, including programmable logic devices (PLDs), such as field programmable gate arrays (FPGAs), programmable array logic (PAL) devices, electrically programmable logic and memory devices and standard cell-based devices, as well as application specific integrated circuits (ASICs). Some other possibilities for implementing aspects of the molecular self-assembly systems and methods include: microcontrollers with memory (such as electronically erasable programmable read only memory (EEPROM)), embedded microprocessors, firmware, software, etc. Furthermore, aspects of the molecular self-assembly systems and methods may be embodied in microprocessors having software-based circuit emulation, discrete logic (sequential and combinatorial), custom devices, fuzzy (neural) logic, quantum devices, and hybrids of any of the above device types. Of course the underlying device technologies may be provided in a variety of component types, e.g., metal-oxide semiconductor field-effect transistor (MOSFET) technologies like complementary metal-oxide semiconductor (CMOS), bipolar technologies like emitter-coupled logic (ECL), polymer technologies (e.g., silicon-conjugated polymer and metal-conjugated polymer-metal structures), mixed analog and digital, etc.

It should be noted that the various components disclosed herein may be described and expressed (or represented) as data and/or instructions embodied in various computer-readable media. Computer-readable media in which such data and/or instructions may be embodied include, but are not limited to, non-volatile storage media in various forms (e.g., optical, magnetic or semiconductor storage media) and carrier waves that may be used to transfer such formatted data and/or instructions through wireless, optical, or wired signaling media or any combination thereof. Examples of transfers of such data and/or instructions by carrier waves include, but are not limited to, transfers (uploads, downloads, e-mail, etc.) over the Internet and/or other computer networks via one or more data transfer protocols (e.g., HTTP, FTP, SMTP, etc.). When received within a computer system via one or more computer-readable media, such data and/or instruction-based expressions of the above described components may be processed by a processing entity (e.g., one or more processors) within the computer system in conjunction with execution of one or more other computer programs.

Unless the context clearly requires otherwise, throughout the description and the claims, the words “comprise,” “comprising,” and the like are to be construed in an inclusive sense as opposed to an exclusive or exhaustive sense; that is to say, in a sense of “including, but not limited to.” Words using the singular or plural number also include the plural or singular number respectively. Additionally, the words “herein,” “hereunder,” “above,” “below,” and words of similar import refer to this application as a whole and not to any particular portions of this application. When the word “or” is used in reference to a list of two or more items, that word covers all of the following interpretations of the word: any of the items in the list, all of the items in the list and any combination of the items in the list.

The above description of illustrated embodiments of the molecular self-assembly systems and methods is not intended to be exhaustive or to limit the molecular self-assembly systems and methods to the precise form disclosed. While specific embodiments of, and examples for, the molecular self-assembly systems and methods are described herein for illustrative purposes, various equivalent modifications are possible within the scope of the molecular self-assembly systems and methods, as those skilled in the relevant art will recognize. The teachings of the molecular self-assembly systems and methods provided herein can be applied to other processing systems and methods, not only for the systems and methods described above.

The elements and acts of the various embodiments described above can be combined to provide further embodiments. These and other changes can be made to the molecular self-assembly systems and methods in light of the above detailed description.

In general, in the following claims, the terms used should not be construed to limit the molecular self-assembly systems and methods to the specific embodiments disclosed in the specification and the claims, but should be construed to include all processing systems that operate under the claims. Accordingly, the molecular self-assembly systems and methods are not limited by the disclosure, but instead the scope of the molecular self-assembly systems and methods is to be determined entirely by the claims.

While certain aspects of the molecular self-assembly systems and methods are presented below in certain claim forms, the inventors contemplate the various aspects of the molecular self-assembly systems and methods in any number of claim forms. Accordingly, the inventors reserve the right to add additional claims after filing the application to pursue such additional claim forms for other aspects of the molecular self-assembly systems and methods.

What is claimed is:

1. A system comprising:
at least one interface configured to receive at least one substrate;
at least one module coupled to the interface, the at least one module including at least one molecular self-assembly processing module; and
at least one handler coupled to the interface and configured to move the substrate between the interface and the at least one module.

2. The system of claim 1, further comprising processing the at least one substrate using the at least one module, wherein the processing includes forming a masking layer on at least one dielectric region of the substrate and forming a capping layer on at least one electrically conductive region of the substrate.

3. The system of claim 2, wherein forming the masking layer comprises selectively forming a molecularly self-assembled layer on the dielectric region.

4. The system of claim 2, wherein forming the masking layer comprises forming masking layer material on the dielectric region and the electrically conductive region and removing the masking layer material from the electrically conductive region.

5. The system of claim 2, wherein forming the capping layer comprises selectively forming capping layer material on the electrically conductive region.

6. The system of claim 5, wherein the masking layer inhibits capping layer formation on the dielectric region and generates a selective capping layer.

7. The system of claim 1, wherein the at least one module includes at least one other module selected from at least one of a pre-processing module and a post-processing module.

8. The system of claim 7, wherein the at least one module includes a plurality of modules, wherein each module of the plurality of modules includes at least one of a plurality of different processes as appropriate to processes contained in at least one other of the plurality of modules.

9. The system of claim 2, further comprising forming a dielectric barrier layer over the electrically conductive region and the dielectric region after forming the masking layer and the capping layer.

10. The system of claim 9, wherein the dielectric barrier layer covers at least one of the capping layer and the masking layer.

11. The system of claim 2, further comprising removing the masking layer after forming the capping layer.

12. The system of claim 11, further comprising forming a dielectric barrier layer over the electrically conductive region and the dielectric region after forming the masking layer and the capping layer.

13. The system of claim 12, wherein the dielectric barrier layer covers at least one of the capping layer and the dielectric region.

14. The system of claim 2, wherein forming masking layer material comprises forming a molecularly self-assembled layer on the dielectric region and the electrically conductive regions.

15. The system of claim 2, wherein forming the capping layer comprises forming capping layer material on the masking layer and the electrically conductive region and removing capping layer material formed on the masking layer.

16. The system of claim 1, wherein the at least one module includes at least one of wet processing modules, dry processing modules, and treatment modules.

17. The system of claim 16, wherein the wet processing modules include at least one of clean modules, rinse modules, dry modules, electrolesss deposition modules, and electrochemical deposition modules.

18. The system of claim 16, wherein the dry processing modules include plasma processing modules.

19. The system of claim 16, wherein the treatment modules include at least one of annealing modules, vaporization modules, ultraviolet (UV) treatment modules, and e-beam treatment modules.

20. The system of claim 1, wherein the substrate includes one or more of silicon, glass, plastic, semiconductors, and wafers.

21. The system of claim 1, further comprising at least one controller coupled to control an environment, wherein the environment includes at least one of an internal environment that is internal to the at least one module and an external environment that is external to the at least one module, wherein the controller controls at least one of temperature, pressure, and composition of the environment.

22. The system of claim 21, wherein the controller controls the pressure of the environment at one or more pre-specified pressures, wherein the pre-specified pressures include atmospheric pressure, at least one pressure below atmospheric pressure, and at least one pressure above atmospheric pressure.

23. The system of claim 21, wherein the controller controls the temperature of the environment at one or more pre-specified temperatures.

24. The system of claim 21, wherein the controller controls the composition of the environment to include one or more pre-specified gases at one or more pre-specified compositions.
